(19) United States
(12) Patent Application Publication
(10) Pub. No.: US 2025/0079348 A1
(43) Pub. Date: Mar. 6, 2025

(54) PACKAGE COMPRISING A SUBSTRATE WITH AN EMBEDDED PASSIVE DEVICE

(71) Applicant: QUALCOMM Incorporated, San Diego, CA (US)

(72) Inventors: Kuiwon KANG, San Diego, CA (US); Hong Bok WE, San Diego, CA (US); Michelle Yejin KIM, Carlsbad, CA (US)

(21) Appl. No.: 18/458,650

(22) Filed: Aug. 30, 2023

(51) Int. Cl. H01L 23/64; H01L 21/768; H01L 23/00; H01L 23/29; H01L 23/31; H01L 23/498

(52) U.S. Cl. CPC H01L 23/642; H01L 21/76802; H01L 21/76877; H01L 23/293; H01L 23/3121; H01L 23/49822; H01L 24/16; H01L 2224/16227; H01L 2924/1205

(57) ABSTRACT

A substrate comprising: a core layer comprising a cavity; an embedded passive device located at least partially in the cavity of the core layer, wherein the embedded passive device comprises a plurality of pad interconnects; a polyimide layer coupled to a surface of the embedded passive device; at least one dielectric layer coupled to the core layer; and a plurality of interconnects located at least partially in the at least one dielectric layer.

### FIELD

Various features relate to packages and substrates.

### BACKGROUND

Packages can include a substrate, an integrated device and passive devices. The substrate may include a plurality of interconnects. Passive devices help in the proper operation of the package and any integrated devices that may be electrically coupled to passive devices. There is an ongoing need to provide smaller packages with improved performances, such as packages with improved passive device performance and/or passive devices with reliable and robust joint connections in the package.

### SUMMARY

Various features relate to packages and substrates.

One example provides a substrate comprising a core layer comprising a cavity; an embedded passive device located at least partially in the cavity of the core layer, wherein the embedded passive device comprises a plurality of pad interconnects; a polyimide layer coupled to a surface of the embedded passive device; at least one dielectric layer coupled to the core layer; and a plurality of interconnects located at least partially in the at least one dielectric layer.

Another example provides a package comprising: an integrated device; and a substrate coupled to the integrated device. The substrate comprises a core layer comprising a cavity; an embedded passive device located at least partially in the cavity of the core layer, wherein the embedded passive device comprises a plurality of pad interconnects; a polyimide layer coupled to a surface of the embedded passive device; at least one dielectric layer coupled to the core layer; and a plurality of interconnects located at least partially in the at least one dielectric layer.

Another example provides a method for fabricating a substrate. The method provides a core layer. The method forms a plurality of interconnects in the core layer and on surfaces of the core layer. The method forms a cavity in the core layer. The method provides an embedded passive device in the cavity of the core layer, wherein the embedded passive device includes a plurality of pad interconnects and a polyimide layer. The method forms at least one dielectric layer coupled to (i) the core layer and (ii) the embedded passive device. The method forms a plurality of interconnects located at least partially in the at least one dielectric layer, wherein forming the plurality of interconnects includes forming a plurality of via interconnects coupled to the plurality of pad interconnects, and wherein the plurality of via interconnects extend through part of the at least one dielectric layer and the polyimide.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary profile view of a substrate with an embedded passive device.

FIG. 2 illustrates a close up view of an exemplary profile view of an embedded passive device in a substrate.

FIG. 3 illustrates an exemplary profile view of a substrate with an embedded passive device.

FIG. 4 illustrates a close up view of an exemplary profile view of an embedded passive device in a substrate.

FIG. 5 illustrates an exemplary plan view of an embedded passive device in a substrate.

FIG. 6 illustrates an exemplary profile view of a package that includes a substrate with an embedded passive device.

FIG. 7 illustrates an exemplary profile view of an embedded passive device.

FIGS. 8A-8G illustrate an exemplary sequence for fabricating a substrate with an embedded passive device.

FIG. 9 illustrates an exemplary sequence for fabricating a substrate with an embedded passive device.

FIG. 10 illustrates an exemplary profile view of another substrate with an embedded passive device.

FIG. 11 illustrates an exemplary profile view of a substrate with an embedded passive device.

FIG. 12 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising an integrated device; and a substrate coupled to the integrated device. The substrate comprises a core layer comprising a cavity; an embedded passive device located at least partially in the cavity of the core layer, wherein the embedded passive device comprises a plurality of pad interconnects; a polyimide layer coupled to a surface of the embedded passive device; at least one dielectric layer coupled to the core layer; and a plurality of interconnects located at least partially in the at least one dielectric layer. The embedded passive device may include a deep trench capacitor. In at least some implementations, the use of the polyimide layer helps provide an embedded passive device in the substrate with reliable and robust joint connections with interconnects of the substrate, which ensure robust and reliable electrical

### Exemplary Package With a Substrate Comprising an Embedded Passive Device

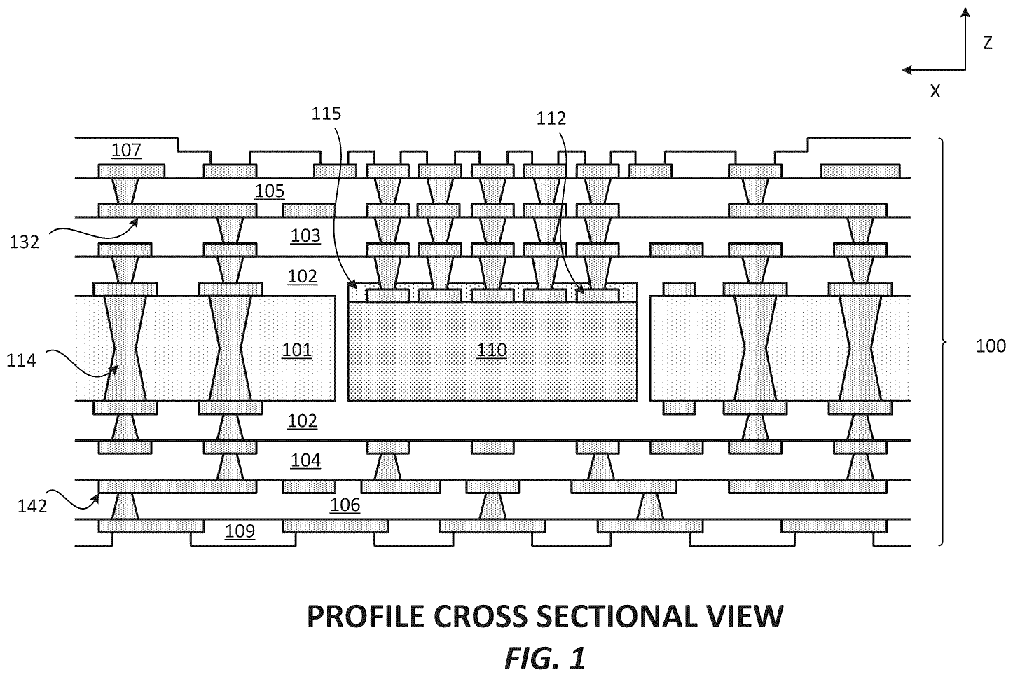

FIG. 1 illustrates a profile view of a substrate 100 that includes an embedded passive device and a polyimide layer. The substrate 100 may be part of a package that includes an integrated device. The substrate 100 includes a core layer 101, a dielectric layer 102, a dielectric layer 103, a dielectric layer 104, a dielectric layer 105, a dielectric layer 106, a solder resist layer 107, a solder resist layer 109, an embedded passive device 110, a polyimide layer 115, a plurality of via interconnects 114, a plurality of interconnects 132 and a plurality of interconnects 142. The embedded passive device 110 may include a silicon capacitor, a deep trench capacitor (DTC) and/or a deep trench capacitor (DTC) device. A silicon capacitor may be a capacitor that is formed on a silicon substrate.

The core layer 101 includes a cavity that is at least partially filled and/or at least partially occupied by the embedded passive device 110 and the dielectric layer 102. The core layer 101 may laterally surround the embedded passive device 110. The embedded passive device 110 may include a plurality of pad interconnects 112. The polyimide layer 115 may be coupled to and touching a surface of the embedded passive device 110. For example, the polyimide layer 115 may be coupled to and touching the surface of the embedded passive device 110 that includes the plurality of pad interconnects 112. The polyimide layer 115 may be a different material from the dielectric layer 102. In some implementations, the dielectric layer 102, the dielectric layer 103, the dielectric layer 104, the dielectric layer 105, the dielectric layer 106 may include prepreg and/or Ajinomoto Build-up Film (ABF). However, the dielectric layer 102, the dielectric layer 103, the dielectric layer 104, the dielectric layer 105, the dielectric layer 106 may be a different type of dielectric. The solder resist layer 107 is coupled to a surface of the dielectric layer 105. The solder resist layer 109 is coupled to a surface of the dielectric layer 106. The core layer 101 may be a type of dielectric layer. The core layer 101 may be a type of a dielectric. The core layer 101 may include a different material and/or a same material as the at least one dielectric layer 102. The at least one dielectric layer

The plurality of via interconnects 114 are located in the core layer 101. The plurality of via interconnects 114 are coupled to the plurality of interconnects 132 and the plurality of interconnects 142. The plurality of via interconnects 144 may have different shapes for different implementations. The plurality of interconnects 132 may be located at least partially in the dielectric layer 102, the dielectric layer 103 and/or the dielectric layer 105. The plurality of interconnects 142 may be located at least partially in the dielectric layer 102, the dielectric layer 104 and/or the dielectric layer 106.

As will be further described below, some interconnects (e.g., via interconnects) from the plurality of interconnects 132 may be coupled (e.g., directly coupled, indirectly coupled) to the plurality of pad interconnects 112 of the embedded passive device 110. Moreover, some interconnects (e.g., via interconnects) from the plurality of interconnects 132 may be touching the polyimide layer 115 and the plurality of pad interconnects 112.

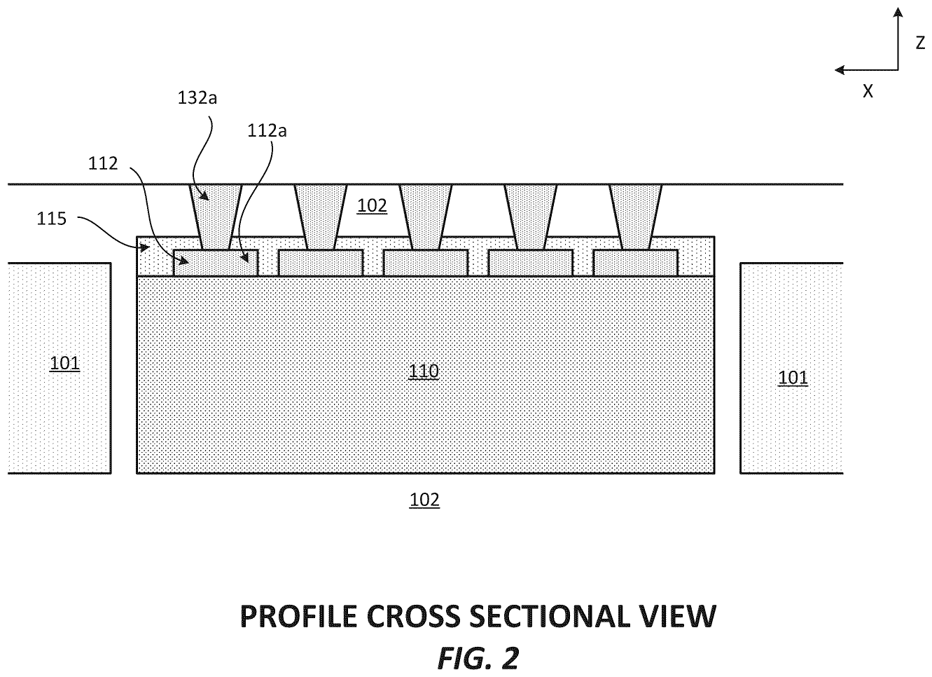

FIG. 2 illustrates a close up view of an embedded passive device 110 located in the substrate 100. The embedded passive device 110 is at least partially surrounded by the dielectric layer 102 and/or the core layer 101. The embedded passive device 110 is located in a cavity of the core layer 101. Part of the cavity of the core layer 101 may be at least partially filled with the dielectric layer 102. The dielectric layer 102 may touch several surfaces of the embedded passive device 110. The embedded passive device 110 may include the plurality of pad interconnects 112. The polyimide layer 115 is coupled to a surface of the embedded passive device 110 that includes the plurality of pad interconnects 112. The polyimide layer 115 may be touching the surface of the embedded passive device 110 and at least part of the plurality of pad interconnects 112.

FIG. 2 also illustrates that some interconnects from the plurality of interconnects 132 are directly coupled to and touching the plurality of pad interconnects 112. For example, the interconnect 132a from the plurality of interconnects 132, is coupled to and touching the pad interconnect 112a from the plurality of pad interconnects 112. The interconnect 132a may be a via interconnect. The interconnect 132a may be touching the polyimide layer 115 and the dielectric layer 102. For example, a side wall of the interconnect 132a may be touching the polyimide layer 115 and the dielectric layer 102. However, in some implementations, a side wall of the interconnect 132a may not be touching the polyimide layer 115. For example, in some implementations, the dielectric layer 102 may be located between the side wall of the interconnect 132a and the polyimide layer 115. In some implementations, the polyimide layer 115 may touch the side walls of none, some or all of the interconnects from the plurality of interconnects 132. In some implementations, the polyimide layer 115 may cover some portions of the surface of the embedded passive device 110. The thickness of the polyimide layer 115 may be greater than the thickness of the plurality of pad interconnects 112. Different implementations may use a plurality of pad interconnects 112 with different sizes, space and/or pitch. In some implementations, the plurality of pad interconnects 112 may have a diameter in a range of about 110-130 micrometers. In some implementations, the plurality of pad interconnects 112 may have a space between neighboring pad interconnects in a range of about 10-20 micrometers. In some implementations, the plurality of pad interconnects 112 may have a pitch between neighboring pad interconnects in a range of about 120-150 micrometers. The above dimensions are exemplary. Other implementations of the plurality of pad interconnects 112 may have diameters, spaces and/or pitches that may be greater or less than the values mentioned above.

As will be further described in below, the use of the polyimide layer 115 helps ensure the proper alignment and position of the embedded passive device 110 in the core layer 101 during the fabrication of a substrate with the embedded passive device. In at least some embodiments, without the polyimide layer 115, the embedded passive device 110 may move (e.g., lift) during the fabrication of the substrate, resulting in potential misalignment of interconnects and a defective substrate. For example, the embedded passive device 110 may move (e.g., lift) when a dielectric layer is formed around the embedded passive device 110. This may be the case for bigger and/or thicker embedded passive devices. The polyimide layer 115 helps ensure that the embedded passive device 110 does not move (or minimally moves), thus ensuring proper alignment and connections of interconnects to the embedded passive device 110.

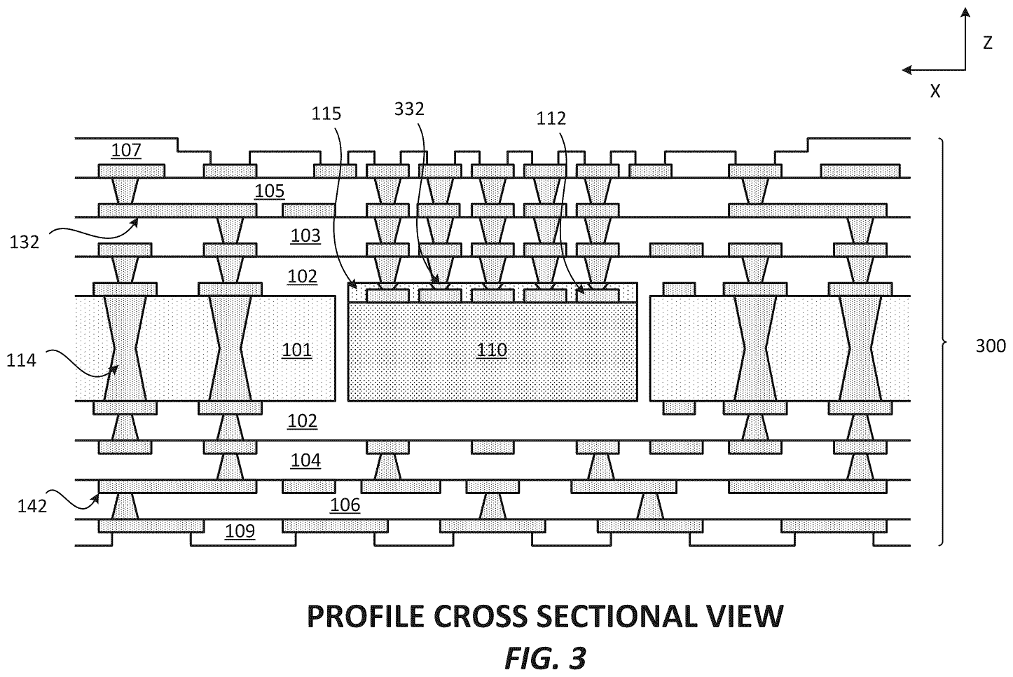

FIG. 3 illustrates a profile view of a substrate 300 that includes an embedded passive device and a polyimide layer. The substrate 300 may be part of a package that includes an integrated device. The substrate 300 is similar to the substrate 100, and thus includes similar components as the substrate 100. The substrate 300 may include stacked via interconnects that are coupled to the plurality of pad interconnects of the embedded passive device.

The substrate 300 includes a core layer 101, a dielectric layer 102, a dielectric layer 103, a dielectric layer 104, a dielectric layer 105, a dielectric layer 106, a solder resist layer 107, a solder resist layer 109, an embedded passive device 110, a polyimide layer 115, a plurality of via interconnects 114, a plurality of interconnects 132 and a plurality of interconnects 142. The plurality of interconnects 132 may include a plurality of via interconnects 332. The plurality of via interconnects 332 may include stacked vias. The plurality of via interconnects 332 may be coupled to other interconnects from the plurality of interconnects 132.

As will be further described below, some via interconnects from the plurality of via interconnects 332 may be coupled (e.g., directly coupled, indirectly coupled) to the plurality of pad interconnects 112 of the embedded passive device 110. Moreover, at least some via interconnects from the plurality of via interconnects 332 may be touching the polyimide layer 115 and the plurality of pad interconnects 112. For example, a side wall of a via interconnect from the plurality of via interconnects 332 may touch the polyimide layer 115.

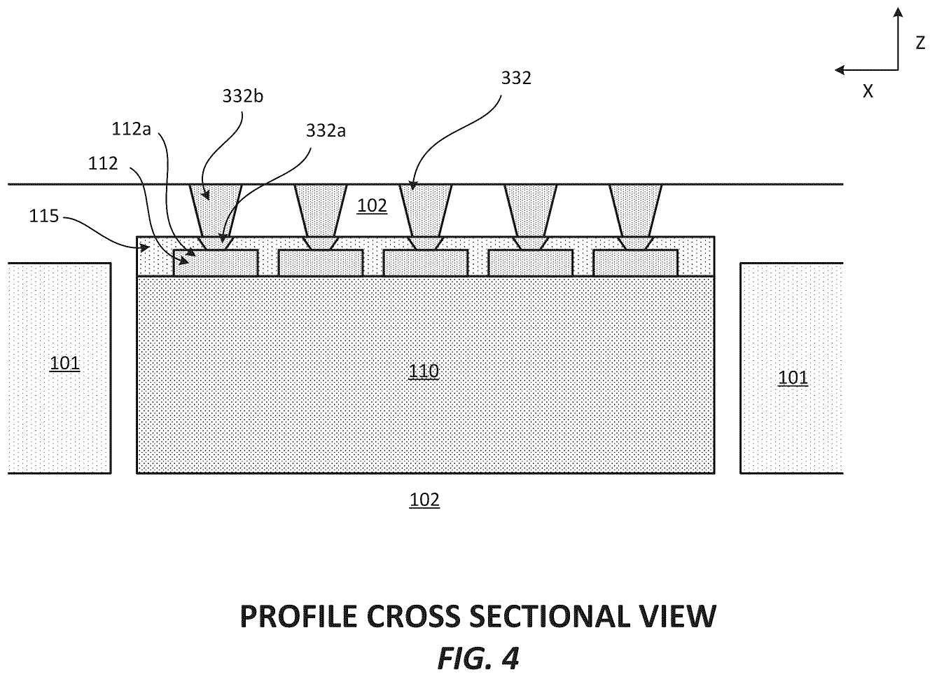

FIG. 4 illustrates a close up view of an embedded passive device 110 located in the substrate 300. The embedded passive device 110 is at least partially surrounded by the dielectric layer 102 and/or the core layer 101. The embedded passive device 110 is located in a cavity of the core layer 101. Part of the cavity of the core layer 101 may be filled with the dielectric layer 102. The dielectric layer 102 may touch several surfaces of the embedded passive device 110. The embedded passive device 110 may include the plurality of pad interconnects 112. The polyimide layer 115 is coupled to a surface of the embedded passive device 110 that includes the plurality of pad interconnects 112. The polyimide layer 115 may be touching the surface of the embedded passive device 110 and at least part of the plurality of pad interconnects 112.

FIG. 4 also illustrates that some via interconnects from the plurality of via interconnects 332 are directly coupled to and touching the plurality of pad interconnects 112. For example, the via interconnect 332b from the plurality of interconnects 332, is coupled to and touching the pad interconnect 112a from the plurality of pad interconnects 112. The interconnect 332b may be touching the polyimide layer 115 and the dielectric layer 102. For example, a side wall of the interconnect 332b may be touching the polyimide layer 115 and the dielectric layer 102. The thickness of the polyimide layer 115 may be greater than the thickness of the plurality of pad interconnects 112.

FIG. 4 illustrates that a via interconnect may be defined as two via interconnects that are touching each other without an intervening pad interconnect or trace interconnect, and/or that a via interconnect may be formed and/or defined by two or more via interconnects. For example, a via interconnect 332b may be coupled to and touching the via interconnect 332a. The via interconnect 332a and the via interconnect 332b may be considered as one via interconnect or two via interconnects. When considered as one via interconnect, the via interconnect 332a may be considered as a first via portion interconnect and the via interconnect 332b may be considered as a second via portion interconnect. In some implementations, the via interconnect 332a and the via interconnect 332b may be stacked via interconnects. The portion of the via interconnect 332a that is touching the portion of the via interconnect 332b may be have different widths and/or diameters. The via interconnect 332a may be located in the polyimide layer 115. The via interconnect 332b may be located in the dielectric layer 102. In some implementations, the polyimide layer 115 may touch at least a portion of via interconnect 332b.

As will be further described in below, the use of the polyimide layer 115 helps ensure the proper alignment and position of the embedded passive device 110 in the core layer 101 during the fabrication of a substrate. In at least some embodiments, without the polyimide layer 115, the embedded passive device 110 may move during the fabrication of the substrate, resulting in potential misalignment of interconnects and a defective substrate.

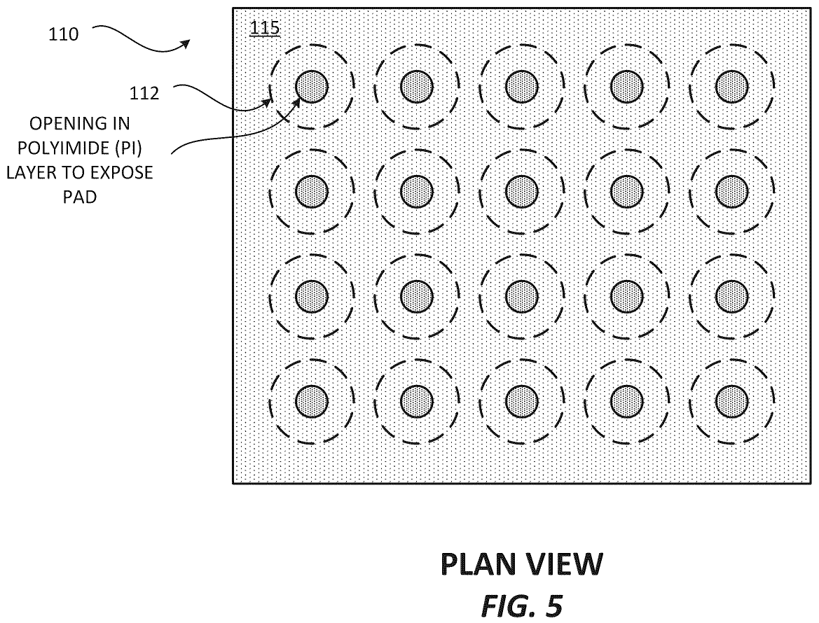

FIG. 5 illustrates a plan view of the embedded passive device 110. The polyimide layer 115 may be coupled to and touching a surface of the embedded passive device 110. The polyimide layer 115 may cover portions of the plurality of pad interconnects 112. There may be openings in the polyimide layer 115 that exposes portions of the plurality of pad interconnects 112. A plurality of via interconnects (e.g., from the plurality of via interconnects 332, from the plurality of interconnects 132) may be coupled to the plurality of pad interconnects 112 through the openings in the polyimide layer 115. In some implementations, the polyimide layer 115 may cover a portion of the surface of the embedded passive device 110.

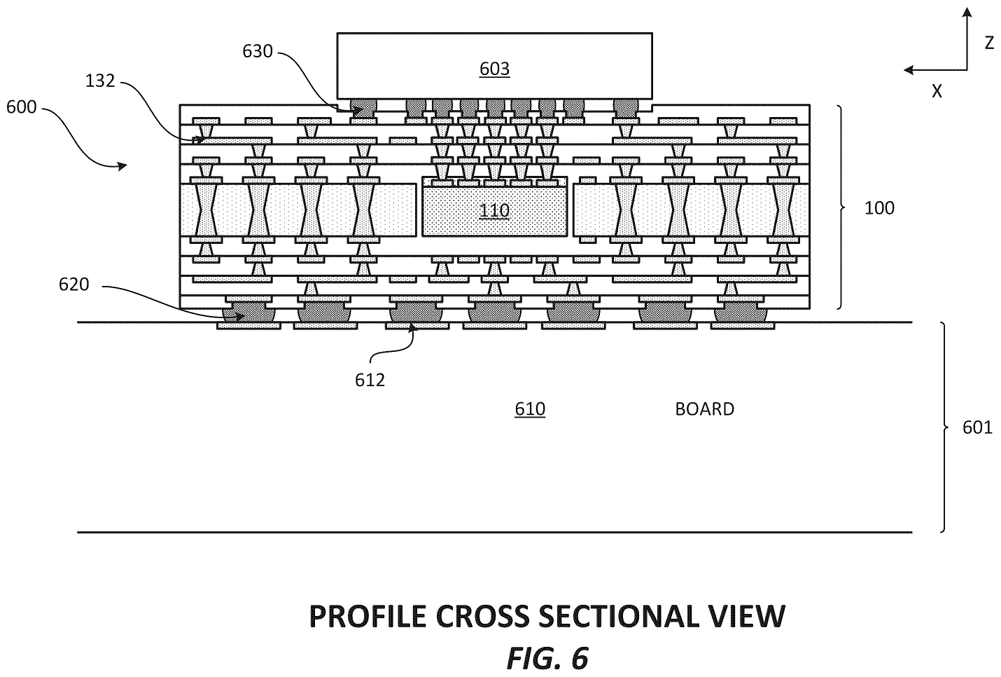

FIG. 6 illustrates a package 600 that includes a substrate 100 and an integrated device 603. The package 600 is coupled to a board 601 through a plurality of solder interconnects 620. The board 601 includes at least one board dielectric layer 610 and a plurality of board interconnects 612. The integrated device 603 is coupled to the substrate 100 through at least a plurality of solder interconnects 630. In some implementations, the integrated device 603 may be coupled to the substrate 100 through the plurality of solder interconnects 630 and/or a plurality of pillar interconnects (not shown). The plurality of solder interconnects 630 and/or the plurality of pillar interconnects may be referred as a plurality of bump interconnects.

As mentioned above, the substrate 100 includes an embedded passive device 110 and a polyimide layer 115. The integrated device 603 may be configured to be electrically coupled to the embedded passive device 110 located in the substrate 100. At least one electrical path between the integrated device 603 and the embedded passive device 110 may include (i) at least one solder interconnect from the plurality of solder interconnects 630, (ii) some interconnects from the plurality of interconnects 132 and (iii) at least one pad interconnect from the plurality of pad interconnects 112.

The integrated device 603 may be configured to be electrically coupled to the board 601 through (i) solder interconnects from the plurality of solder interconnects 630, (ii) interconnects from the plurality of interconnects from the substrate 100, and (iii) solder interconnects from the plurality of solder interconnects 620.

In some implementations, instead of the substrate 100, the substrate 300 may be implemented in the package 600. In such instances, the integrated device 603 may be coupled to the substrate 300 through the plurality of solder interconnects 630 and/or a plurality of pillar interconnects (not shown). The integrated device 603 may be configured to be electrically coupled to the embedded passive device 110 located in the substrate 300. At least one electrical path between the integrated device 603 and the embedded passive device 110 of the substrate 300 may include (i) at least one solder interconnect from the plurality of solder interconnects 630, (ii) some interconnects from the plurality of interconnects 132, (iii) at least one via interconnect from the plurality of via interconnects 332 and (iv) at least one pad interconnect from the plurality of pad interconnects 112.

The integrated device 603 may be configured to be electrically coupled to the board 601 through (i) solder interconnects from the plurality of solder interconnects 630, (ii) interconnects from the plurality of interconnects from the substrate 300, and (iii) solder interconnects from the plurality of solder interconnects 620.

### Exemplary Embedded Passive Device

Different implementations may provide different types of embedded passive device. In some implementations, the embedded passive device 110 includes an integrated passive device (IPD). In some implementations, the embedded passive device 110 includes a deep trench capacitor (e.g., trench capacitor device). In some implementations, the embedded passive device 110 is implemented as an embedded passive chiplet.

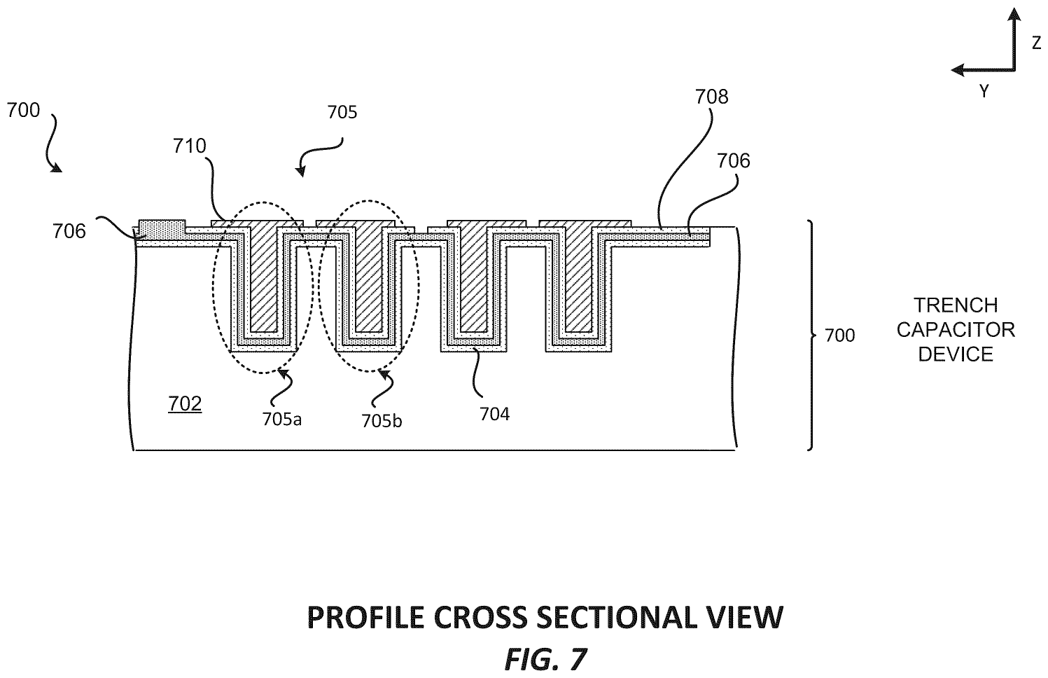

FIG. 7 illustrates a cross sectional profile view of an embedded passive device 700 that is configured as a trench capacitor device. The embedded passive device 700 may be an integrated passive device that includes multiple trench capacitors (e.g., deep trench capacitors). The embedded passive device 700 may be a means for trench capacitance. The embedded passive device 700 may represent the embedded passive device 110. The embedded passive device 700 includes a front side and a back side. The front side of the embedded passive device 700 may include the plurality of trench capacitors. Although not shown in FIG. 7, the embedded passive device 700 may include a polyimide layer (e.g., 115) coupled to a surface (e.g., front side surface) of the embedded passive device 700.

The embedded passive device 700 includes an embedded passive device substrate 702 and a plurality of trench capacitors 705. A plurality of solder interconnects (not shown) may be coupled to the embedded passive device 700. The embedded passive device substrate 702 may include silicon (Si). The embedded passive device substrate 702 may include a plurality of trenches and/or cavities over which capacitors may be formed.

The plurality of trench capacitors 705 include a trench capacitor 705a and a trench capacitor 705b. The trench capacitor 705a and the trench capacitor 705b may be configured to be part of a same capacitor (e.g., first capacitor, first trench capacitor). The trench capacitor 705a and the trench capacitor 705b may be configured to be coupled to and/or part of a first power distribution network (PDN). The trench capacitor 705a and the trench capacitor 705b may be configured to be part of a first electrical path for a first power for a package. The trench capacitor 705a and the trench capacitor 705b may be configured to be coupled to integrated device(s).

As shown in FIG. 7, the embedded passive device 700 includes the embedded passive device substrate 702, an oxide layer 704, a first electrically conductive layer 706, a dielectric layer 708, and a second electrically conductive layer 710. The first electrically conductive layer 706 and/or the second electrically conductive layer 710 may include polysilicon. The oxide layer 704 and/or the dielectric layer 708 may include SiO₂ (e.g., low-pressure chemical vapor deposition (LPCVD) SiO₂) or Si₃N₄(e.g., LPCVD Si₃N₄). Portions of the oxide layer 704, the first electrically conductive layer 706, the dielectric layer 708, and the second electrically conductive layer 710 may be located in trenches and/or cavities of the embedded passive device substrate 702. It is noted that an embedded passive device substrate 702 may be considered to have a trench or a cavity, even if the trench or the cavity is filled with one or more materials.

The trench capacitor 705a (e.g., first trench capacitor, first capacitor, means for first trench capacitance) may be defined by (i) a first portion of the oxide layer 704, (ii) a first portion of the first electrically conductive layer 706, (iii) a first portion of the dielectric layer 708, and (iv) a first portion of the second electrically conductive layer 710 that are located in a trench (e.g., first trench) of the embedded passive device substrate 702.

The trench capacitor 705b (e.g., second trench capacitor, second capacitor, means for second trench capacitance) may be defined by (i) a second portion of the oxide layer 704, (ii) a second portion of the first electrically conductive layer 706, (iii) a second portion of the dielectric layer 708, and (iv) a second portion of the second electrically conductive layer 710 that are located in a trench (e.g., second trench) of the embedded passive device substrate 702. It is noted that trench capacitor 705b may be part of a same capacitor as the trench capacitor 705a. That is, the trench capacitor 705a and the trench capacitor 705b may be configured to be electrically coupled together to form a capacitor (e.g., first capacitor) with a greater capacitance.

As mentioned above, the embedded passive device 700 may include a polyimide layer 115 that is coupled to a front side of the embedded passive device 700. The front side of the embedded passive device 700 may be a side that includes the trench capacitors.

An integrated device may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include transistors. An integrated device may be an example of an electrical component and/or electrical device. In some implementations, an integrated device may include a chiplet. A chiplet may be fabricated using a process that provides better yields compared to other processes that are used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that perform several functions may reduce the overall cost of a package relative to using a single chip to perform all of the functions of a package.

### Exemplary Sequence for Fabricating a Substrate With an Embedded Passive Device and a Polyimide Layer

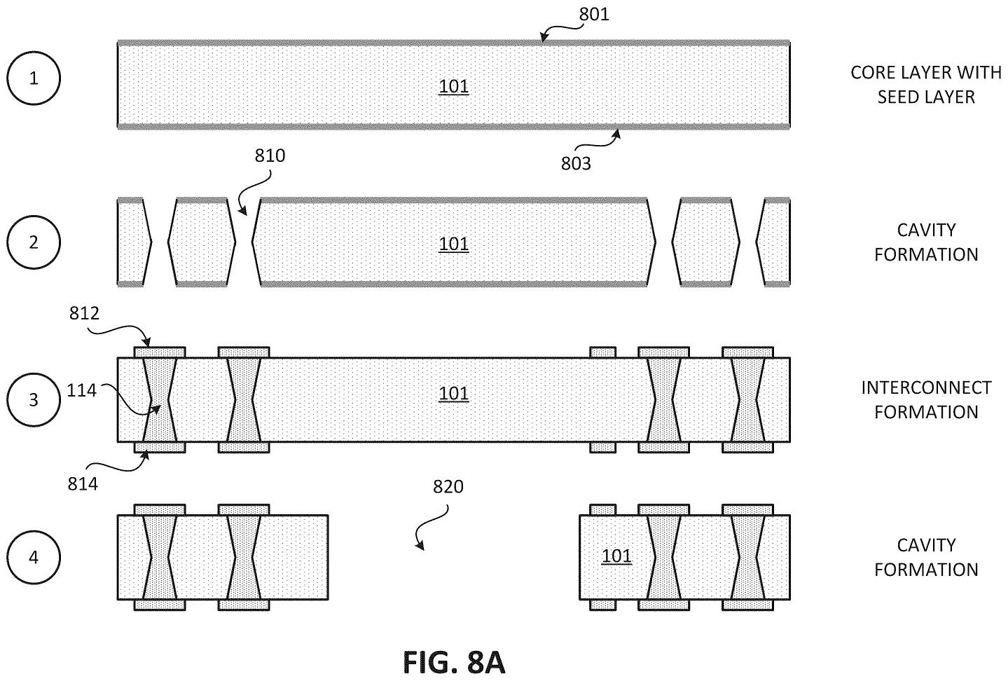

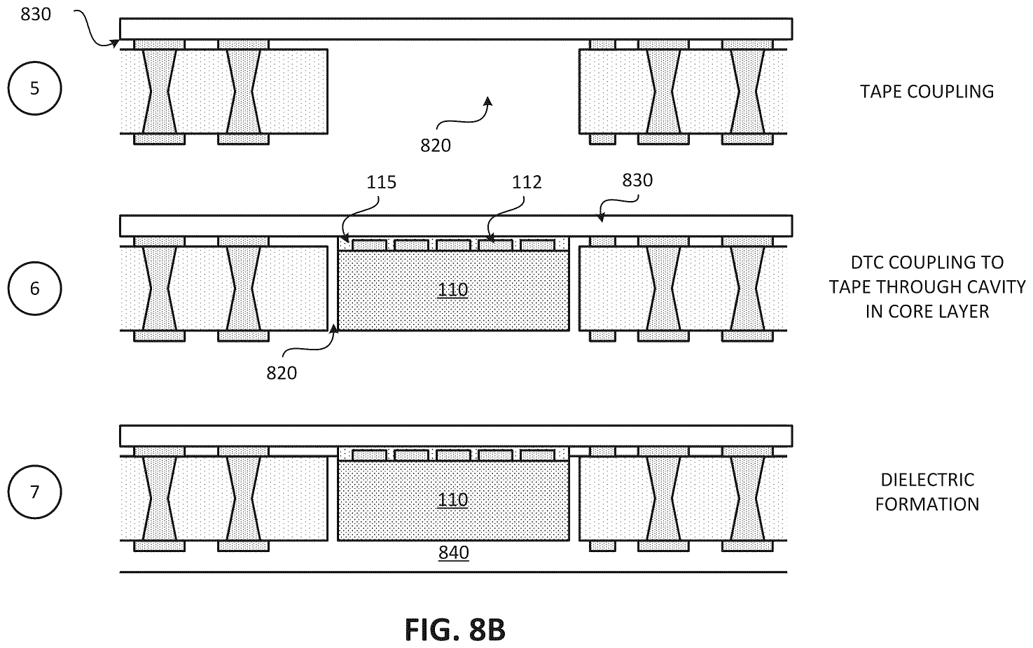

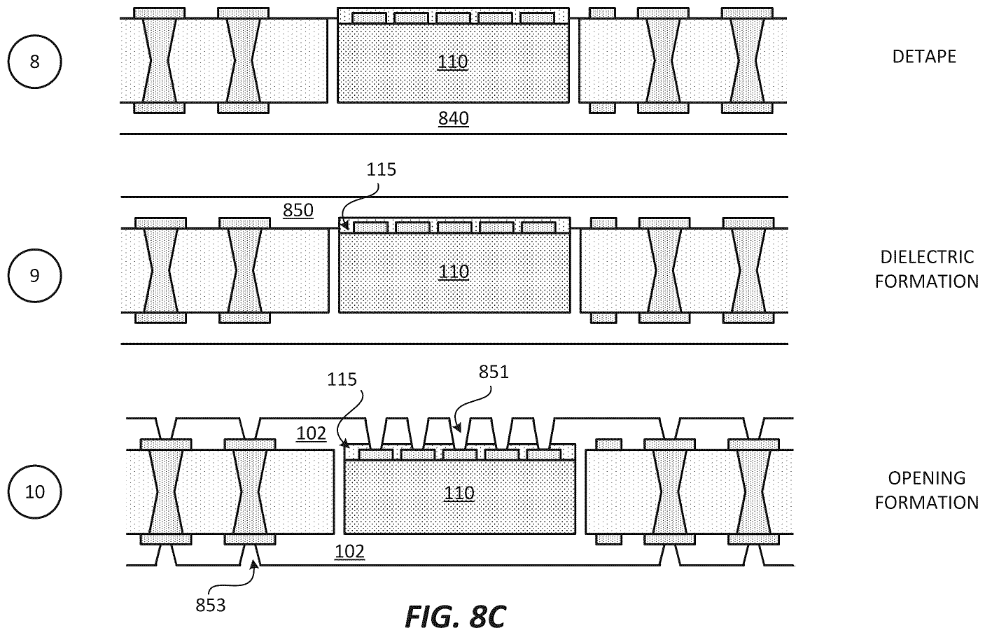

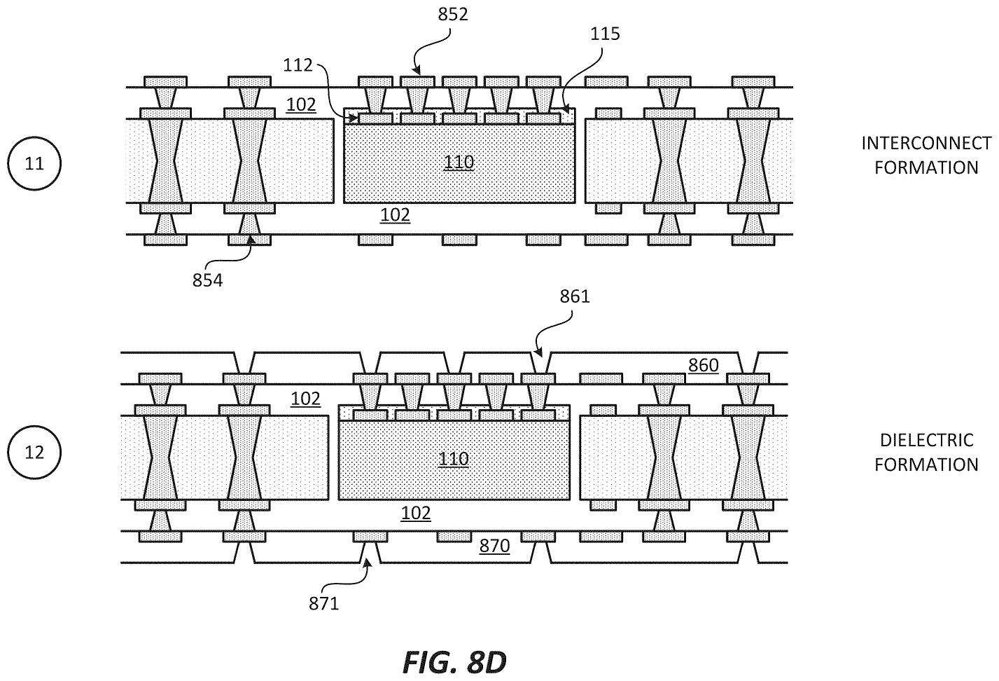

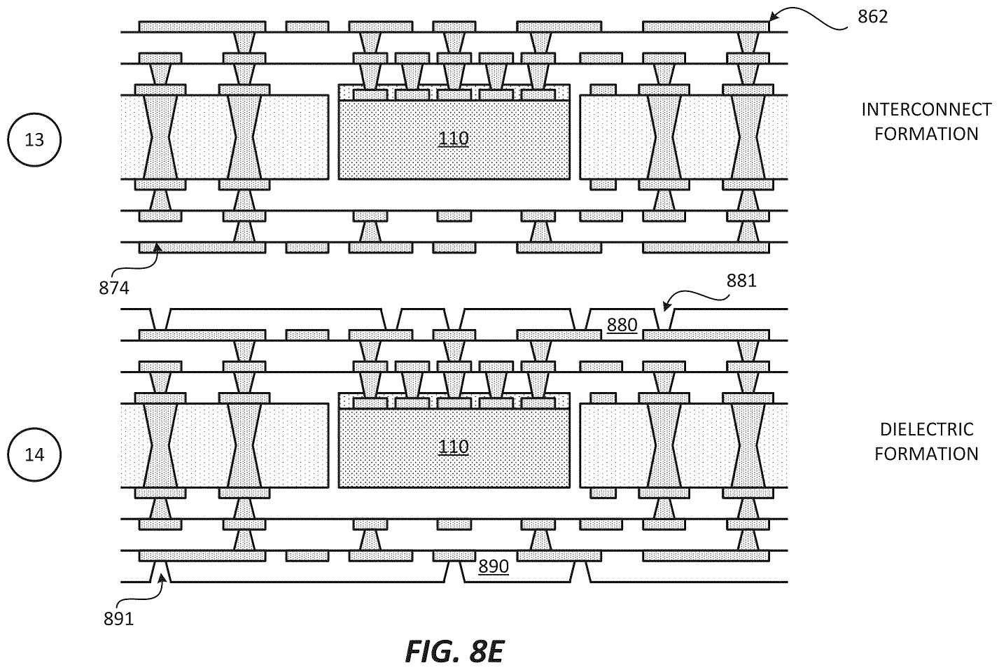

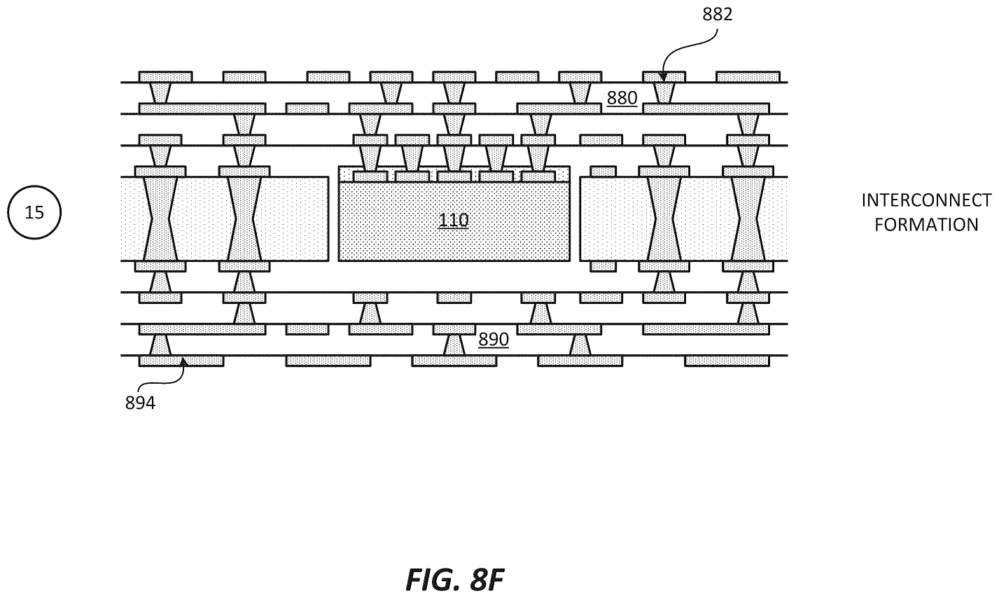

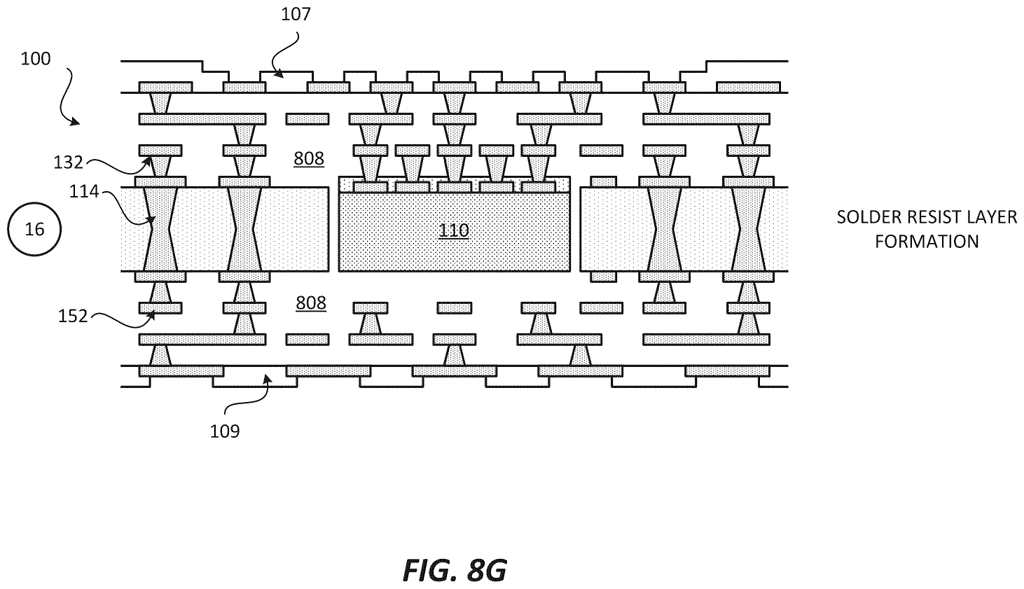

FIGS. 8A-8G illustrate an exemplary sequence for providing or fabricating a substrate with an embedded passive device and a polyimide layer. In some implementations, the sequence of FIGS. 8A-8G may be used to provide or fabricate any of the substrates described in the disclosure. In some implementations, the sequence of FIGS. 8A-8G may be used to provide or fabricate the substrate 100 described in the disclosure.

It should be noted that the sequence of FIGS. 8A-8G may combine one or more stages in order to simplify and/or clarify the sequence for providing or fabricating a substrate. In some implementations, the order of the processes may be changed or modified. In some implementations, one or more of processes may be replaced or substituted without departing from the spirit of the disclosure. Different implementations may fabricate a substrate differently.

Stage 1, as shown in FIG. 8A, illustrates a state after a core layer 101 is provided. The core layer 101 may include a seed layer 801 coupled to a first surface of the core layer 101 and a seed layer 803 coupled to a second surface of the core layer 101.

Stage 2 illustrates a state after a plurality of cavities 810 are formed in the core layer 101. The plurality of cavities 810 may be formed through the seed layer 801 and the seed layer 803. A laser process (e.g., laser ablation) may be used to form the plurality of cavities 810. However, different implementations may use different processes to form the plurality of cavities 810. The plurality of cavities 810 may extend through the thickness of the core layer 101, the seed layer 801 and/or the seed layer 803.

Stage 3 illustrates a state after a plurality of via interconnects 114, a plurality of interconnects 812 and a plurality of interconnects 814. The plurality of via interconnects 114 may be formed in the plurality of cavities 810. The plurality of interconnects 812 may be formed and coupled to a first surface of the core layer 101. In some implementations, part of the seed layer 801 may be part of the plurality of interconnects 812. The plurality of interconnects 812 may be coupled to the plurality of via interconnects 114. The plurality of interconnects 814 may be formed and coupled to a second surface of the core layer 101. In some implementations, part of the seed layer 803 may be part of the plurality of interconnects 814. The plurality of interconnects 814 may be coupled to the plurality of via interconnects 114. A plating process and a patterning process may be used to form the plurality of via interconnects 114, the plurality of interconnects 812 and/or the plurality of interconnects 814.

Stage 4 illustrates a state after a cavity 820 is formed in the core layer 101. The cavity 820 may be formed through the core layer 101. A laser process (e.g., laser ablation) may be used to form the cavity 820. However, different implementations may use different processes to form the cavity 820. The cavity 820 may extend through the thickness of the core layer 101.

Stage 5, as shown in FIG. 8B, illustrates a state after the core layer 101 with the cavity 820 is coupled to a tape 830. The tape 830 may be a type of carrier. The tape 830 may include an adhesive. The tape 830 may be touching the plurality of interconnects 812 and/or the core layer 101.

Stage 6 illustrates a state after an embedded passive device 110 that includes a plurality of pad interconnects 112 and a polyimide layer 115, is coupled to the tape 830. The embedded passive device 110 is coupled to the tape 830 through the cavity 820 in the core layer 101. The embedded passive device 110 is located at least partially in the cavity 820 of the core layer 101. In some implementations, the polyimide layer 115 may cover an entire surface of the embedded passive device 110, including the plurality of pad interconnects 112. In some implementations, the polyimide layer 115 may cover a portion of the entire surface of the embedded passive device 110. For example, the polyimide layer 115 may cover part of the plurality of pad interconnects 112 and may include openings over the plurality of pad interconnects 112. The polyimide layer 115 may be touching the tape 830.

Stage 7 illustrates a state after a dielectric layer 840 is formed. The dielectric layer 840 fills at least part of the cavity 820 of the core layer 101. The dielectric layer 840 is coupled to the embedded passive device 110 and the core layer 101. The dielectric layer 840 may be coupled to a second surface (e.g., bottom surface) of the core layer 101. A deposition process and/or a lamination process may be used to form the dielectric layer 840. In some implementations, the dielectric layer 840 may include a polymer. In some implementations, the dielectric layer 840 may include prepreg. In some implementations, the dielectric layer 840 may include die attach film. The polyimide layer 115 helps ensure that the embedded passive device 110 is firmly coupled to the tape 830 when the dielectric layer 840 is formed and/or provided. Without the polyimide layer 115, the embedded passive device 110 may be more likely to move (e.g., lift) when the dielectric layer 840 is formed (e.g., due to pressure when the dielectric layer 840 fills the cavity 820 of the core layer 101), resulting in potential misalignment of interconnects when subsequent interconnects are formed that are coupled to the embedded passive device 110. This may be the case for bigger and/or thicker embedded passive devices (e.g., embedded passive devices with a height that is about 400 micrometers or greater). However, the use of the polyimide layer 115 is not limited to embedded passive devices with a height that is 400 micrometers or greater. In some implementations, the polyimide layer 115 may be used with embedded passive devices that have a height that is less than 400 micrometers. The polyimide layer 115 helps ensure that the embedded passive device 110 does not move (or minimally moves), thus ensuring proper alignment and connections of interconnects to the embedded passive device 110.

Stage 8, as shown in FIG. 8C, illustrates a state after the tape 830 is decoupled from the core layer 101 and the embedded passive device 110. The tape 830 may be detached and/or peeled off.

Stage 9 illustrates a state after the dielectric layer 850 is formed and coupled to the core layer 101 and the embedded passive device 110. The dielectric layer 850 may fill part of the cavity 820. The dielectric layer 850 may be coupled to the embedded passive device 110 and a first surface (e.g., top surface) of the core layer. The dielectric layer 850 may touch and cover the polyimide layer 115. A deposition process and/or a lamination process may be used to form the dielectric layer 850. In some implementations, the dielectric layer 850 may include a polymer. In some implementations, the dielectric layer 850 may include prepreg. In some implementations, the dielectric layer 850 may include die attach film. The dielectric layer 850 may be the same material as the dielectric layer 840. The dielectric layer 840 and the dielectric layer 850 may be represented as the dielectric layer 102. The dielectric layer 102 may be different from the polyimide layer 115. The dielectric layer 102 is coupled to the core layer 101 and the embedded passive device 110.

Stage 10 illustrates a state after a plurality of cavities 851 are formed through a surface (e.g., first surface, top surface) of the dielectric layer 102 and the polyimide layer 115. The plurality of cavities 851 may expose part of the plurality of pad interconnects 112 of the embedded passive device 110. In some implementations, there may be cavities in the polyimide layer 115 before the plurality of cavities 851 may be formed. A laser process (e.g., laser ablation process) may be used to form the plurality of cavities 851 in the dielectric layer 102 and the polyimide layer 115. However, different implementations may use different processes to form the plurality of cavities 851. The plurality of cavities 851 may have different shapes.

Stage 10 also illustrates a state after a plurality of cavities 853 are formed through another surface (e.g., second surface, bottom surface) of the dielectric layer 102. A laser process (e.g., laser ablation process) may be used to form the plurality of cavities 853 in the dielectric layer 102. However, different implementations may use different processes to form the plurality of cavities 853.

Stage 11, as shown in FIG. 8D, illustrates a state after a plurality of interconnects 852 and a plurality of interconnects 854 are formed in at least the dielectric layer 102. Some interconnects (e.g., via interconnects) from the plurality of interconnects 852 may be formed at least partially in the polyimide layer 115. Some interconnects (e.g., via interconnects) from the plurality of interconnects 852 may be directly touching the plurality of pad interconnects 112 of the embedded passive device 110. The polyimide layer 115 may touch a side surface of some interconnects (e.g., via interconnects) from the plurality of interconnects 852. The shape and/or size of the via interconnects that are coupled to and touching the plurality of pad interconnects 112 may vary with different implementations. In some implementations, at least one of the interconnects from the plurality of interconnects 852 are the same and/or similar to the interconnects 132, as shown in FIG. 2. In some implementations, at least one of the interconnects from the plurality of interconnects 852 are the same and/or similar to the via interconnect from the plurality of via interconnects 332, as shown in FIG. 4. In some implementations, the shape and/or design of the via interconnects may be dependent on how the cavities in the polyimide layer 115 and/or the dielectric layer 102 may be formed. In some implementations, the dielectric layer 102 and the polyimide layer 115 may have different properties, and thus different shapes of the cavities may be formed in the dielectric layer 102 and the polyimide layer 115, in response to using a laser process. The plurality of interconnects 852 are coupled to the plurality of via interconnects 812. The plurality of interconnects 854 are coupled to the plurality of via interconnects 814.

Stage 12 illustrates a state after a dielectric layer 860 and the dielectric layer 870 are formed. The dielectric layer 860 may include a plurality of cavities 861. The dielectric layer 870 may include a plurality of cavities 871. The dielectric layer 860 may be formed and coupled to a first surface (e.g., top surface) of the dielectric layer 102. The dielectric layer 870 may be formed and coupled to a second surface (e.g., bottom surface) of the dielectric layer 102. In some implementations, the dielectric layer 860 and/or the dielectric layer 870 may include a polymer. In some implementations, the dielectric layer 860 and/or the dielectric layer 870 may include Ajinomoto Build-up Film (ABF). In some implementations, the dielectric layer 860 and/or the dielectric layer 870 may include prepreg. The dielectric layer 860 and/or the dielectric layer 870 may be the same or different from the dielectric layer 102.

The plurality of cavities 861 are formed through a surface (e.g., first surface, top surface) of the dielectric layer 860. A laser process (e.g., laser ablation process) may be used to form the plurality of cavities 861 in the dielectric layer 860. However, different implementations may use different processes to form the plurality of cavities 861. The plurality of cavities 871 are formed through a surface (e.g., second surface, bottom surface) of the dielectric layer 870. A laser process (e.g., laser ablation process) may be used to form the plurality of cavities 871 in the dielectric layer 870. However, different implementations may use different processes to form the plurality of cavities 871. In some implementations, the dielectric layer 860, the dielectric layer 870, the plurality of cavities 861 and/or the plurality of cavities 871 may be formed through a deposition process, a lamination process, an exposure process and/or a development process.

Stage 13, as shown in FIG. 8E, illustrates a state after a plurality of interconnects 862 are formed in at least the dielectric layer 860. The plurality of interconnects 862 are coupled to the plurality of interconnects 852. Stage 13 also illustrates and describes a state after a plurality of interconnects 874 are formed in at least the dielectric layer 870. The plurality of interconnects 874 are coupled to the plurality of interconnects 854. A plating process and a patterning process may be used to form the plurality of interconnects 862 and/or the plurality of interconnects 874.

Stage 14 illustrates a state after a dielectric layer 880 and the dielectric layer 890 are formed. The dielectric layer 880 may include a plurality of cavities 881. The dielectric layer 890 may include a plurality of cavities 891. The dielectric layer 880 may be formed and coupled to a first surface (e.g., top surface) of the dielectric layer 860. The dielectric layer 890 may be formed and coupled to a second surface (e.g., bottom surface) of the dielectric layer 870. In some implementations, the dielectric layer 880 and/or the dielectric layer 890 may include a polymer. In some implementations, the dielectric layer 880 and/or the dielectric layer 890 may include Ajinomoto Build-up Film (ABF). In some implementations, the dielectric layer 880 and/or the dielectric layer 890 may include prepreg. The dielectric layer 880 and/or the dielectric layer 890 may be the same or different from the dielectric layer 102, the dielectric layer 860 and/or the dielectric layer 870.

The plurality of cavities 881 are formed through a surface (e.g., first surface, top surface) of the dielectric layer 880. A laser process (e.g., laser ablation process) may be used to form the plurality of cavities 881 in the dielectric layer 880. However, different implementations may use different processes to form the plurality of cavities 881. The plurality of cavities 891 are formed through a surface (e.g., second surface, bottom surface) of the dielectric layer 890. A laser process (e.g., laser ablation process) may be used to form the plurality of cavities 891 in the dielectric layer 890. However, different implementations may use different processes to form the plurality of cavities 891. In some implementations, the dielectric layer 880, the dielectric layer 890, the plurality of cavities 881 and/or the plurality of cavities 891 may be formed through a deposition process, a lamination process, an exposure process and/or a development process.

Stage 15, as shown in FIG. 8F, illustrates a state after a plurality of interconnects 882 are formed in at least the dielectric layer 880. The plurality of interconnects 882 are coupled to the plurality of interconnects 862. Stage 15 also illustrates and describes a state after a plurality of interconnects 894 are formed in at least the dielectric layer 890. The plurality of interconnects 894 are coupled to the plurality of interconnects 874. A plating process and a patterning process may be used to form the plurality of interconnects 882 and/or the plurality of interconnects 894.

Stage 16, as shown in FIG. 8G, illustrates a state after a solder resist layer 107 is formed and patterned. The solder resist layer 107 may be coupled to the dielectric layer 808. The dielectric layer 808 may be at least one dielectric layer that represents all and/or part of, the dielectric layer 102, a dielectric layer 860, and/or a dielectric layer 880. A deposition, a lamination, an exposure, a development and/or an etching process may be used to form and pattern the solder resist layer 107. The plurality of interconnects 132 may be located at least in the dielectric layer 808. The plurality of interconnects 132 may represent all and/or part of the plurality of interconnects 812, the plurality of interconnects 852, the plurality of interconnects 862 and/or the plurality of interconnects 882.

Stage 16 also illustrates and describes a state after a solder resist layer 109 is formed and patterned. The solder resist layer 109 may be coupled to the dielectric layer 809. The dielectric layer 809 may be at least one dielectric layer that represents all and/or part of, the dielectric layer 102, a dielectric layer 870, and/or a dielectric layer 890. A deposition, a lamination, an exposure, a development and/or an etching process may be used to form and pattern the solder resist layer 109. The plurality of interconnects 142 may be located at least in the dielectric layer 809. The plurality of interconnects 142 may represent all and/or part of the plurality of interconnects 814, the plurality of interconnects 854, the plurality of interconnects 874 and/or the plurality of interconnects 894.

### Exemplary Flow Diagram of a Method for Fabricating a Substrate With an Embedded Passive Device and a Polyimide Layer

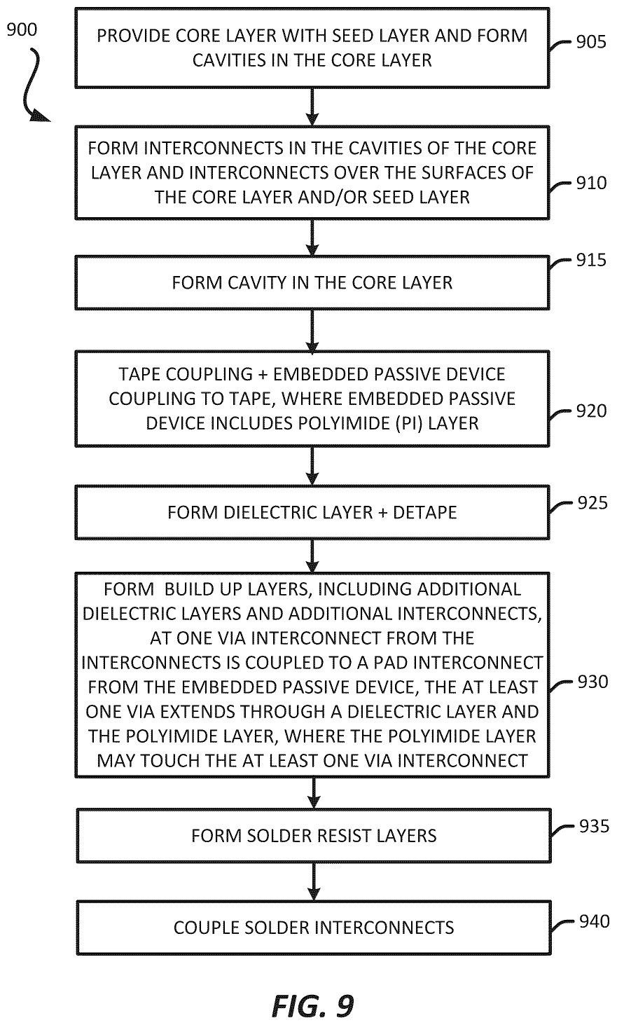

In some implementations, fabricating a substrate includes several processes. FIG. 9 illustrates an exemplary flow diagram of a method 900 for providing or fabricating a substrate with an embedded passive device and a polyimide layer. In some implementations, the method 900 of FIG. 9 may be used to provide or fabricate the substrate 100.

It should be noted that the method 900 of FIG. 9 may combine one or more processes in order to simplify and/or clarify the method for providing or fabricating a substrate. In some implementations, the order of the processes may be changed or modified.

The method provides (at 905) a core layer with seed layers and forms cavities in the core layer through the seed layer. Stage 1 of FIG. 8A, illustrates and describes an example of a state after a core layer 101 is provided. The core layer 101 may include a seed layer 801 coupled to a first surface of the core layer 101 and a seed layer 803 coupled to a second surface of the core layer 101.

Stage 2 of FIG. 8A, illustrates and describes an example of a state after a plurality of cavities 810 are formed in the core layer 101. The plurality of cavities 810 may be formed through the seed layer 801 and the seed layer 803. A laser process (e.g., laser ablation) may be used to form the plurality of cavities 810. However, different implementations may use different processes to form the plurality of cavities 810. The plurality of cavities 810 may extend through the thickness of the core layer 101, the seed layer 801 and/or the seed layer 803.

The method forms (at 910) via interconnects in the core layer and interconnects on surfaces of the core layer. Stage 3 of FIG. 8A, illustrates and describes an example of a state after a plurality of via interconnects 114, a plurality of interconnects 812 and a plurality of interconnects 814. The plurality of via interconnects 114 may be formed in the plurality of cavities 810. The plurality of interconnects 812 may be formed and coupled to a first surface of the core layer 101. In some implementations, part of the seed layer 801 may be part of the plurality of interconnects 812. The plurality of interconnects 812 may be coupled to the plurality of via interconnects 114. The plurality of interconnects 814 may be formed and coupled to a second surface of the core layer 101. In some implementations, part of the seed layer 803 may be part of the plurality of interconnects 814. The plurality of interconnects 814 may be coupled to the plurality of via interconnects 114. A plating process and a patterning process may be used to form the plurality of via interconnects 114, the plurality of interconnects 812 and/or the plurality of interconnects 814.

The method forms (at 915) a cavity in the core layer. Stage 4 of FIG. 8A, illustrates and describes an example of a state after a cavity 820 is formed in the core layer 101. The cavity 820 may be formed through the core layer 101. A laser process (e.g., laser ablation) may be used to form the cavity 820. However, different implementations may use different processes to form the cavity 820. The cavity 820 may extend through the thickness of the core layer 101 and/or the seed layers (801, 803).

The method couples (at 920) the core layer and an embedded passive device to a tape. The embedded passive device may include a polyimide layer. Stage 5 of FIG. 8B, illustrates and describes an example of a state after the core layer 101 with the cavity 820 is coupled to a tape 830. The tape 830 may be a type of carrier. The tape 830 may include an adhesive. The tape 830 may be touching the plurality of interconnects 812 and/or the core layer 101.

Stage 6 of FIG. 8B, illustrates and describes an example of a state after an embedded passive device 110 that includes a plurality of pad interconnects 112 and a polyimide layer 115, is coupled to the tape 830. The embedded passive device 110 is coupled to the tape 830 through the cavity 820 in the core layer 101. The embedded passive device 110 is located at least partially in the cavity 820 of the core layer 101. In some implementations, the polyimide layer 115 may cover an entire surface of the embedded passive device 110, including the plurality of pad interconnects 112. In some implementations, the polyimide layer 115 may cover a portion of the entire surface of the embedded passive device 110. For example, the polyimide layer 115 may cover part of the plurality of pad interconnects 112 and may include openings over the plurality of pad interconnects 112. The polyimide layer 115 may be touching the tape 830.

The method form (at 925) a dielectric layer and de-tapes. Stage 7 of FIG. 8B, illustrates and describes an example of a state after a dielectric layer 840 is formed. The dielectric layer 840 fills at least part of the cavity 820 of the core layer 101. The dielectric layer 840 is coupled to the embedded passive device 110 and the core layer 101. The dielectric layer 840 may be coupled to a second surface (e.g., bottom surface) of the core layer 101. A deposition process and/or a lamination process may be used to form the dielectric layer 840. In some implementations, the dielectric layer 840 may include a polymer. In some implementations, the dielectric layer 840 may include prepreg. The presence of the polyimide layer 115 may help ensure that the embedded passive device 110 is firmly coupled to the tape 830.

Stage 8 of FIG. 8C, illustrates and describes an example of a state after the tape 830 is decoupled from the core layer 101 and the embedded passive device 110. The tape 830 may be detached and/or peeled off.

The method forms (at 930) build up layers that includes at least one dielectric layer and a plurality of interconnects, where the plurality of interconnects include at least one via interconnect coupled to a pad interconnect from the plurality of pad interconnects of an embedded passive device. The at least one via interconnect may extend through the at least one dielectric layer and a polyimide layer. The polyimide layer may touch the at least one via interconnect coupled to a pad interconnect of the embedded passive device.

Stage 9 of FIG. 8C through Stage 15 of FIG. 8F, illustrate and describe examples of forming a build up layers that includes at least one dielectric layer and a plurality of interconnects. Stage 9 of FIG. 8C, illustrates and describes a state after the dielectric layer 850 is formed and coupled to the core layer 101 and the embedded passive device 110. The dielectric layer 850 may fill at least part of the cavity 820. The dielectric layer 850 may be coupled to the embedded passive device 110 and a first surface (e.g., top surface) of the core layer. The dielectric layer 850 may touch and cover the polyimide layer 115. A deposition process and/or a lamination process may be used to form the dielectric layer 850. In some implementations, the dielectric layer 850 may include a polymer. In some implementations, the dielectric layer 850 may include prepreg. The dielectric layer 850 may be the same material as the dielectric layer 840. The dielectric layer 840 and the dielectric layer 850 may be represented as the dielectric layer 102. The dielectric layer 102 may be different from the polyimide layer 115.

Stage 10 of FIG. 8C, illustrates and describes an example of a state after a plurality of cavities 851 are formed through a surface (e.g., first surface, top surface) of the dielectric layer 102 and the polyimide layer 115. The plurality of cavities 851 may expose part of the plurality of pad interconnects 112 of the embedded passive device 110. In some implementations, there may be cavities in the polyimide layer 115 before the plurality of cavities 851 may be formed. A laser process (e.g., laser ablation process) may be used to form the plurality of cavities 851 in the dielectric layer 102 and the polyimide layer 115. However, different implementations may use different processes to form the plurality of cavities 851. The plurality of cavities 851 may have different shapes.

Stage 10 of FIG. 8C, also illustrates and describes an example of a state after a plurality of cavities 853 are formed through another surface (e.g., second surface, bottom surface) of the dielectric layer 102. A laser process (e.g., laser ablation process) may be used to form the plurality of cavities 853 in the dielectric layer 102. However, different implementations may use different processes to form the plurality of cavities 853.

Stage 11 of FIG. 8D, illustrates and describes an example of a state after a plurality of interconnects 852 and a plurality of interconnects 854 are formed in at least the dielectric layer 102. Some interconnects (e.g., via interconnects) from the plurality of interconnects 852 may be formed at least partially in the polyimide layer 115. Some interconnects (e.g., via interconnects) from the plurality of interconnects 852 may be directly touching the plurality of pad interconnects 112 of the embedded passive device 110. The polyimide layer 115 may touch a side surface of some interconnects (e.g., via interconnects) from the plurality of interconnects 852. The shape and/or size of the via interconnects that are coupled to and touching the plurality of pad interconnects 112 may vary with different implementations. In some implementations, at least one of the interconnects from the plurality of interconnects may be the same and/or similar to the plurality of interconnects 132, as shown in FIG. 2. In some implementations, at least one of the interconnects from the plurality of interconnects 852 are the same and/or similar to the via interconnect from the plurality of via interconnects 332, as shown in FIG. 4. In some implementations, the shape and/or design of the via interconnects may be dependent on how the cavities in the polyimide layer 115 and/or the dielectric layer 102 may be formed. In some implementations, the dielectric layer 102 and the polyimide layer 115 may have different properties, and thus different shapes of the cavities may be formed in the dielectric layer 102 and the polyimide layer 115, in response to using a laser process. The plurality of interconnects 852 are coupled to the plurality of via interconnects 812. The plurality of interconnects 854 are coupled to the plurality of via interconnects 814.

Stage 12 of FIG. 8D, illustrates and describes an example of a state after a dielectric layer 860 and the dielectric layer 870 are formed. The dielectric layer 860 may include a plurality of cavities 861. The dielectric layer 870 may include a plurality of cavities 871. The dielectric layer 860 may be formed and coupled to a first surface (e.g., top surface) of the dielectric layer 102. The dielectric layer 870 may be formed and coupled to a second surface (e.g., bottom surface) of the dielectric layer 102. In some implementations, the dielectric layer 860 and/or the dielectric layer 870 may include a polymer. In some implementations, the dielectric layer 860 and/or the dielectric layer 870 may include Ajinomoto Build-up Film (ABF). In some implementations, the dielectric layer 860 and/or the dielectric layer 870 may include prepreg. The dielectric layer 860 and/or the dielectric layer 870 may be the same or different from the dielectric layer 102.

The plurality of cavities 861 are formed through a surface (e.g., first surface, top surface) of the dielectric layer 860. A laser process (e.g., laser ablation process) may be used to form the plurality of cavities 861 in the dielectric layer 860. However, different implementations may use different processes to form the plurality of cavities 861. The plurality of cavities 871 are formed through a surface (e.g., second surface, bottom surface) of the dielectric layer 870. A laser process (e.g., laser ablation process) may be used to form the plurality of cavities 871 in the dielectric layer 870. However, different implementations may use different processes to form the plurality of cavities 871.

Stage 13 of FIG. 8E, illustrates and describes an example of a state after a plurality of interconnects 862 are formed in at least the dielectric layer 860. The plurality of interconnects 862 are coupled to the plurality of interconnects 852. Stage 13 also illustrates and describes an example of a state after a plurality of interconnects 874 are formed in at least the dielectric layer 870. The plurality of interconnects 874 are coupled to the plurality of interconnects 854. A plating process and a patterning process may be used to form the plurality of interconnects 862 and/or the plurality of interconnects 874.

Stage 14 of FIG. 8E, illustrates and describes an example of a state after a dielectric layer 880 and the dielectric layer 890 are formed. The dielectric layer 880 may include a plurality of cavities 881. The dielectric layer 890 may include a plurality of cavities 891. The dielectric layer 880 may be formed and coupled to a first surface (e.g., top surface) of the dielectric layer 860. The dielectric layer 890 may be formed and coupled to a second surface (e.g., bottom surface) of the dielectric layer 870. In some implementations, the dielectric layer 880 and/or the dielectric layer 890 may include a polymer. In some implementations, the dielectric layer 880 and/or the dielectric layer 890 may include Ajinomoto Build-up Film (ABF). In some implementations, the dielectric layer 880 and/or the dielectric layer 890 may include prepreg. The dielectric layer 880 and/or the dielectric layer 890 may be the same or different from the dielectric layer 102, the dielectric layer 860 and/or the dielectric layer 870.

The plurality of cavities 881 are formed through a surface (e.g., first surface, top surface) of the dielectric layer 880. A laser process (e.g., laser ablation process) may be used to form the plurality of cavities 881 in the dielectric layer 880. However, different implementations may use different processes to form the plurality of cavities 881. The plurality of cavities 891 are formed through a surface (e.g., second surface, bottom surface) of the dielectric layer 890. A laser process (e.g., laser ablation process) may be used to form the plurality of cavities 891 in the dielectric layer 890. However, different implementations may use different processes to form the plurality of cavities 891.

Stage 15 of FIG. 8F, illustrates and describes an example of a state after a plurality of interconnects 882 are formed in at least the dielectric layer 880. The plurality of interconnects 882 are coupled to the plurality of interconnects 862. Stage 15 also illustrates and describes an example of a state after a plurality of interconnects 894 are formed in at least the dielectric layer 890. The plurality of interconnects 894 are coupled to the plurality of interconnects 874. A plating process and a patterning process may be used to form the plurality of interconnects 882 and/or the plurality of interconnects 894.

The method forms (at 935) at least one solder resist layer. Stage 16 of FIG. 8G, illustrates and describes an example of a state after a solder resist layer 107 is formed and patterned. The solder resist layer 107 may be coupled to the dielectric layer 808. The dielectric layer 808 may be at least one dielectric layer that represents all and/or part of, the dielectric layer 102, a dielectric layer 860, and/or a dielectric layer 880. A deposition, a lamination, an exposure, a development and/or an etching process may be used to form and pattern the solder resist layer 107. The plurality of interconnects 132 may be located at least in the dielectric layer 808. The plurality of interconnects 132 may represent all and/or part of the plurality of interconnects 812, the plurality of interconnects 852, the plurality of interconnects 862 and/or the plurality of interconnects 882.

Stage 16 of FIG. 8G, illustrates and describes an example of a state after a solder resist layer 109 is formed and patterned. The solder resist layer 109 may be coupled to the dielectric layer 809. The dielectric layer 809 may be at least one dielectric layer that represents all and/or part of, the dielectric layer 102, a dielectric layer 870, and/or a dielectric layer 890. A deposition, a lamination, an exposure, a development and/or an etching process may be used to form and pattern the solder resist layer 109. The plurality of interconnects 142 may be located at least in the dielectric layer 809. The plurality of interconnects 142 may represent all and/or part of the plurality of interconnects 814, the plurality of interconnects 854, the plurality of interconnects 874 and/or the plurality of interconnects 894.

The method couples (at 940) a plurality of solder interconnects to interconnects of the substrate. In some implementations, a plurality of solder interconnects may be coupled to interconnects of the substrate 100 through openings in the solder resist layer 107 and/or openings in the solder resist layer 109.

Once the substrate (e.g., 100, 300) is provided and/or fabricated, an integrated device (e.g., 603) may be coupled to the substrate through at least a plurality of solder interconnects (e.g., 630). The substrate and the integrated device may then be coupled to a board (e.g., 601) through a plurality of solder interconnects (e.g., 620).

### Exemplary Package With a Substrate Comprising an Embedded Passive Device

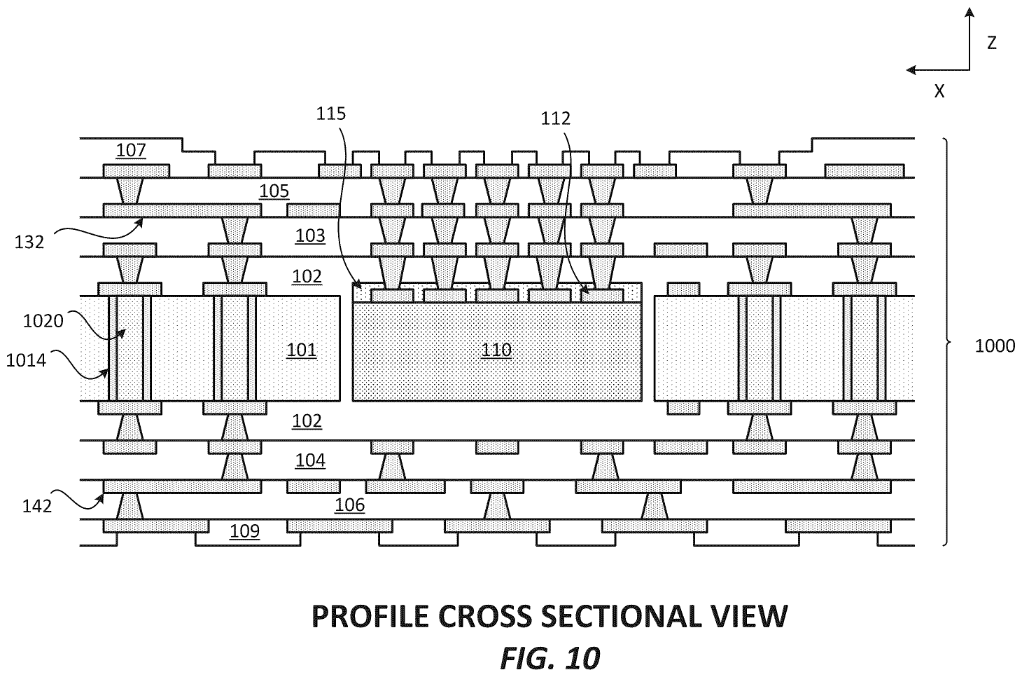

It is noted that different implementations may use different types of substrates. FIG. 10 illustrates a profile view of a substrate 1000 that includes an embedded passive device and a polyimide layer. The substrate 1000 may be part of a package that includes an integrated device. The substrate 1000 includes a core layer 101, a dielectric layer 102, a dielectric layer 103, a dielectric layer 104, a dielectric layer 105, a dielectric layer 106, a solder resist layer 107, a solder resist layer 109, an embedded passive device 110, a polyimide layer 115, a plurality of via interconnects 1014, a plurality of fills 1020, a plurality of interconnects 132 and a plurality of interconnects 142. The embedded passive device 110 may include a deep trench capacitor (DTC) and/or a deep trench capacitor (DTC) device. The substrate 1000 is similar to the substrate 100, and may be configured and/or arranged in a similar manner as the substrate 100. However, the substrate 1000 includes a plurality of via interconnects 1014 that are different from the plurality of via interconnects 114 of the substrate 100. As shown in FIG. 10, the plurality of via interconnects 1014 may have vertical walls. The plurality of via interconnects 1014 may be at least partially filled with the plurality of fills 1020 and/or may laterally surround the plurality of fills 1020. The plurality of fills 1020 may include a plug material fill. The plurality of via interconnects 1014 may be configured to be coupled to the plurality of interconnects 132 and the plurality of interconnects 142.

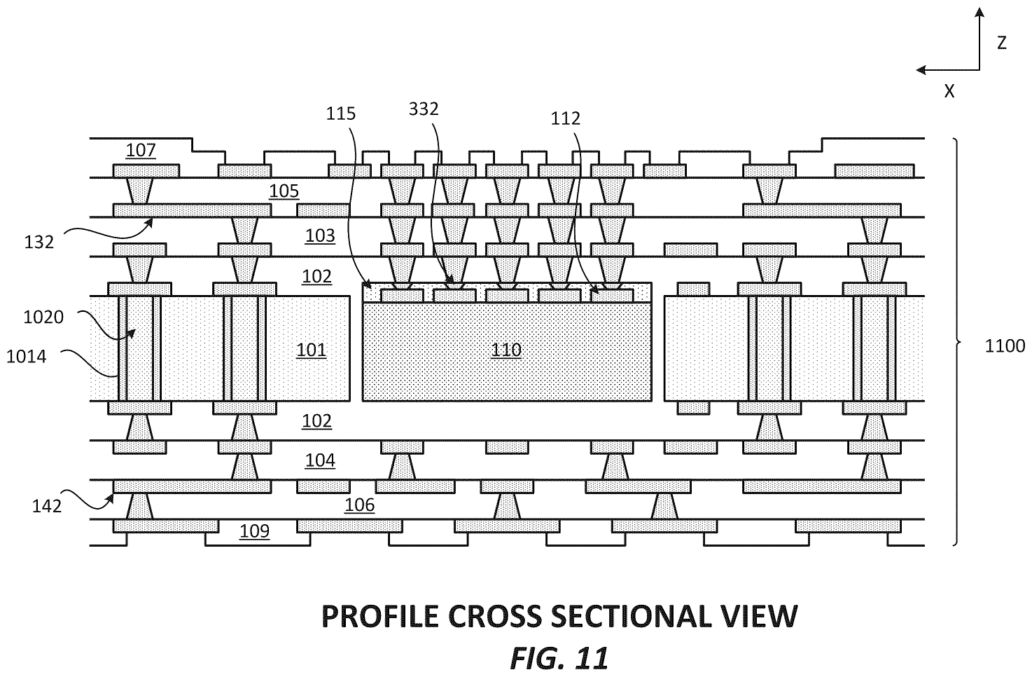

FIG. 11 illustrates a profile view of a substrate 1100 that includes an embedded passive device and a polyimide layer. The substrate 1100 may be part of a package that includes an integrated device. The substrate 1100 is similar to the substrate 300, and thus includes similar components as the substrate 300. The substrate 300 may include stacked via interconnects that are coupled to the plurality of pad interconnects of the embedded passive device.

The substrate 1100 includes a core layer 101, a dielectric layer 102, a dielectric layer 103, a dielectric layer 104, a dielectric layer 105, a dielectric layer 106, a solder resist layer 107, a solder resist layer 109, an embedded passive device 110, a polyimide layer 115, a plurality of via interconnects 1014, a plurality of fills 1020, a plurality of interconnects 132 and a plurality of interconnects 142. The plurality of interconnects 132 may include a plurality of via interconnects 332. The plurality of via interconnects 332 may be include stacked vias. The plurality of via interconnects 332 may be coupled to other interconnects from the plurality of interconnects 132.

The substrate 1100 is similar to the substrate 300, may be configured and/or arranged in a similar manner. However, the substrate 1100 includes a plurality of via interconnects 1014 that are different from the plurality of via interconnects 114 of the substrate 300. As shown in FIG. 11, the plurality of via interconnects 1014 may have vertical walls. The plurality of via interconnects 1014 may be filled with the plurality of fills 1020 and/or may laterally surround the plurality of fills 1020. The plurality of fills 1020 may include a plug material fill. The plurality of via interconnects 1014 may be configured to be coupled to the plurality of interconnects 132 and the plurality of interconnects 142.

The substrate 1000 and/or the substrate 1100 may replace any of the substrates implemented in a package. In some implementations, the substrate 1000 and/or the substrate 1100 may be fabricated using the sequence described in at least FIGS. 8A-8G, with some modifications. For example, the cavities that are formed in the core layer, as shown in stage 2 of FIG. 8A, may be formed with mechanical drilling, and the plurality of via interconnects 1014 may be formed using a plating process, and the plurality of fills 1020 may be formed after the plurality of via interconnects 1014 are formed.

### Exemplary Electronic Devices

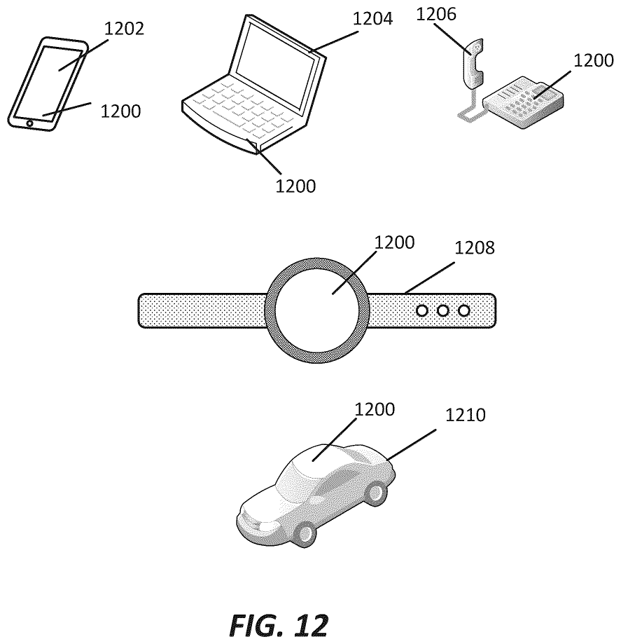

FIG. 12 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1202, a laptop computer device 1204, a fixed location terminal device 1206, a wearable device 1208, or automotive vehicle 1210 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-7, 8A-8G, and/or 9-12 may be rearranged and/or combined into a single component, process, feature or function or embodied in several components, processes, or functions. Additional elements, components, processes, and/or functions may also be added without departing from the disclosure. It should also be noted FIGS. 1-7, 8A-8G, and/or 9-12 and its corresponding description in the present disclosure is not limited to dies and/or ICs. In some implementations, FIGS. 1-7, 8A-8G, and/or 9-12 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A substrate comprising a core layer comprising a cavity; an embedded passive device located at least partially in the cavity of the core layer, wherein the embedded passive device comprises a plurality of pad interconnects; a polyimide layer coupled to a surface of the embedded passive device; at least one dielectric layer located above and below the core layer; and a plurality of interconnects located at least partially in the at least one dielectric layer.

Aspect 2: The substrate of aspect 1, wherein the at least one dielectric layer includes a different material from the polyimide layer.

Aspect 3: The substrate of aspects 1 through 2, further comprising a plurality of via interconnects coupled to the plurality of pad interconnects, wherein the plurality of via interconnects touch the at least one dielectric layer and the polyimide layer.

Aspect 4: The substrate of claims 1 through 3, wherein the polyimide layer is coupled to a surface of the embedded passive device comprising the plurality of pad interconnects.

Aspect 5: The substrate of aspects 1 through 4, wherein the embedded passive device includes an integrated passive device (IPD).

Aspect 6: The substrate of aspects 1 through 5, wherein the embedded passive device includes a deep trench capacitor.

Aspect 7: The substrate of aspects 1 through 6, wherein the plurality of interconnects are configured to be electrically coupled to the embedded passive device.

Aspect 8: The substrate of aspects 1 through 7, wherein the at least one dielectric layer is located in at least part of the cavity of the core layer.

Aspect 9: The substrate of aspects 1 through 8, wherein the at least one dielectric layer laterally surrounds and touch the embedded passive device.

Aspect 10: The substrate of aspects 1 through 9, wherein the substrate is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 11: A package comprising an integrated device; and a substrate coupled to the integrated device. The substrate comprises a core layer comprising a cavity; an embedded passive device located at least partially in the cavity of the core layer, wherein the embedded passive device comprises a plurality of pad interconnects; a polyimide layer coupled to a surface of the embedded passive device; at least one dielectric layer located above and below the core layer; and a plurality of interconnects located at least partially in the at least one dielectric layer.

Aspect 12: The package of aspect 11, wherein the at least one dielectric layer includes a different material from the polyimide layer.

Aspect 13: The package of aspects 11 through 12, wherein the substrate further comprises a plurality of via interconnects coupled to the plurality of pad interconnects, wherein the plurality of via interconnects touch the at least one dielectric layer and the polyimide layer.

Aspect 14: The package of aspects 11 through 13, wherein the polyimide layer is coupled to a surface of the embedded passive device comprising the plurality of pad interconnects.

Aspect 15: The package of aspects 11 through 14, wherein the embedded passive device includes an integrated passive device (IPD).

Aspect 16: The package of aspects 11 through 15, wherein the embedded passive device includes a deep trench capacitor.

Aspect 17: The package of aspects 11 through 16, wherein the plurality of interconnects are configured to be electrically coupled to the embedded passive device.

Aspect 18: The package of aspects 11 through 17, wherein the at least one dielectric layer is located in at least part of the cavity of the core layer.

Aspect 19: The package of aspects 11 through 18, wherein the at least one dielectric layer laterally surrounds and touch the embedded passive device.

Aspect 20: The package of aspects 11 through 19, wherein the package is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 21: A method for fabricating a substrate. The method provides a core layer. The method forms a plurality of interconnects in the core layer and on surfaces of the core layer. The method forms a cavity in the core layer. The method provides an embedded passive device in the cavity of the core layer, wherein the embedded passive device includes a plurality of pad interconnects and a polyimide layer. The method forms at least one dielectric layer above and below (i) the core layer and (ii) the embedded passive device. The method forms a plurality of interconnects located at least partially in the at least one dielectric layer, wherein forming the plurality of interconnects includes forming a plurality of via interconnects coupled to the plurality of pad interconnects, and wherein the plurality of via interconnects extend through part of the at least one dielectric layer and the polyimide.

Aspect 22: The method of aspect 21, wherein the at least one dielectric layer includes a different material from the polyimide layer.

Aspect 23: The method of aspects 21 through 22, wherein the plurality of via interconnects touch the at least one dielectric layer and the polyimide layer.

Aspect 24: The method of aspects 21 through 23, wherein the polyimide layer is coupled to a surface of the embedded passive device comprising the plurality of pad interconnects.

Aspect 25: The method of aspects 21 through 24, wherein the embedded passive device includes an integrated passive device (IPD) and/or a deep trench capacitor.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A substrate comprising:
a core layer comprising a cavity;
an embedded passive device located at least partially in the cavity of the core layer, wherein the embedded passive device comprises a plurality of pad interconnects;
a polyimide layer coupled to a surface of the embedded passive device;
at least one dielectric layer coupled to the core layer; and
a plurality of interconnects located at least partially in the at least one dielectric layer.

2. The substrate of claim 1, wherein the at least one dielectric layer includes a different material from the polyimide layer.

3. The substrate of claim 1, further comprising a plurality of via interconnects coupled to the plurality of pad interconnects, wherein the plurality of via interconnects touch the at least one dielectric layer and the polyimide layer.

4. The substrate of claim 1, wherein the polyimide layer is coupled to a surface of the embedded passive device comprising the plurality of pad interconnects.

5. The substrate of claim 1, wherein the embedded passive device includes an integrated passive device (IPD).

6. The substrate of claim 1, wherein the embedded passive device includes a deep trench capacitor.

7. The substrate of claim 1, wherein the plurality of interconnects are configured to be electrically coupled to the embedded passive device.

8. The substrate of claim 1, wherein the at least one dielectric layer is located in at least part of the cavity of the core layer.

9. The substrate of claim 1, wherein the at least one dielectric layer laterally surrounds and touch the embedded passive device.

10. The substrate of claim 1, wherein the substrate is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

11. A package comprising:
an integrated device; and
a substrate coupled to the integrated device, wherein the substrate comprises:
a core layer comprising a cavity;
an embedded passive device located at least partially in the cavity of the core layer, wherein the embedded passive device comprises a plurality of pad interconnects;
a polyimide layer coupled to a surface of the embedded passive device;
at least one dielectric layer coupled to the core layer; and
a plurality of interconnects located at least partially in the at least one dielectric layer.

12. The package of claim 11, wherein the at least one dielectric layer includes a different material from the polyimide layer.

13. The package of claim 11, wherein the substrate further comprises a plurality of via interconnects coupled to the plurality of pad interconnects, wherein the plurality of via interconnects touch the at least one dielectric layer and the polyimide layer.

14. The package of claim 11, wherein the polyimide layer is coupled to a surface of the embedded passive device comprising the plurality of pad interconnects.

15. The package of claim 11, wherein the embedded passive device includes an integrated passive device (IPD).

16. The package of claim 11, wherein the embedded passive device includes a deep trench capacitor.

17. The package of claim 11, wherein the plurality of interconnects are configured to be electrically coupled to the embedded passive device.

18. The package of claim 11, wherein the at least one dielectric layer is located in at least part of the cavity of the core layer.

19. The package of claim 11, wherein the at least one dielectric layer laterally surrounds and touch the embedded passive device.

20. The package of claim 11, wherein the package is implemented in a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

21. A method for fabricating a substrate, comprising:
providing a core layer;
forming a plurality of interconnects in the core layer and on surfaces of the core layer;
forming a cavity in the core layer;
providing an embedded passive device in the cavity of the core layer, wherein the embedded passive device includes a plurality of pad interconnects and a polyimide layer;
forming at least one dielectric layer coupled to (i) the core layer and (ii) the embedded passive device; and
forming a plurality of interconnects located at least partially in the at least one dielectric layer,
wherein forming the plurality of interconnects includes forming a plurality of via interconnects coupled to the plurality of pad interconnects, and
wherein the plurality of via interconnects extend through part of the at least one dielectric layer and the polyimide.

22. The method of claim 21, wherein the at least one dielectric layer includes a different material from the polyimide layer.

23. The method of claim 21, wherein the plurality of via interconnects touch the at least one dielectric layer and the polyimide layer.

24. The method of claim 21, wherein the polyimide layer is coupled to a surface of the embedded passive device comprising the plurality of pad interconnects.

25. The method of claim 21, wherein the embedded passive device includes an integrated passive device (IPD) and/or a deep trench capacitor.
